(19) United States
(12) Patent Application Publication
(10) Pub. No.: US 2010/0230150 A1
(43) Pub. Date: Sep. 16, 2010

(54) MOTHERBOARD

(75) Inventor: CHIH-SHENG HSIEH, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/413,592

(22) Filed: Mar. 29, 2009

(30) Foreign Application Priority Data
Mar. 16, 2009 (CN) 200910300887.5

(51) Int. Cl. H05K 1/16; H05K 1/11

(52) U.S. Cl. 174/260; 174/262

(57) ABSTRACT

A motherboard includes a mounting area, a plurality of first mounting holes, and a plurality of second mounting holes. The mounting area is configured to support an electronic component. The plurality of first mounting holes is defined in the motherboard around the mounting area to bound a first area, and configured to mount a first type of fan. The plurality of second mounting holes is defined in the motherboard around the mounting area to bound a second area, and configured to mount a second type of fan. The first and second areas are concentric with the mounting area, and each of the plurality of second mounting holes is located adjacent to a corresponding one of the plurality of first mounting holes.

### BACKGROUND

1. Technical Field

The present disclosure relates to motherboards and, particularly, to a motherboard with holes for mounting fans.

2. Description of Related Art

A computer system generally includes various components such as a motherboard mounted with a central processing unit (CPU), a storage device such as a hard disc drive, and input/output devices mounted to the motherboard. Therefore, the computer system including the CPU will generate heat when the computer system is operating. The computer system may include a CPU fan mounted directly on the CPU to cool the CPU.

Conventionally, CPU fans may only be mounted to dedicated motherboards. CPU fans designed for one kind of motherboard cannot be attached to another kind of motherboard.

### BRIEF DESCRIPTION OF THE DRAWINGS

FIG. 1 is a partial, schematic view of an embodiment of a motherboard.

FIG. 2 is a schematic view of the motherboard of FIG. 1, together with a first fan.

FIG. 3 is a schematic view of the motherboard of FIG. 1, together with a second fan.

### DETAILED DESCRIPTION

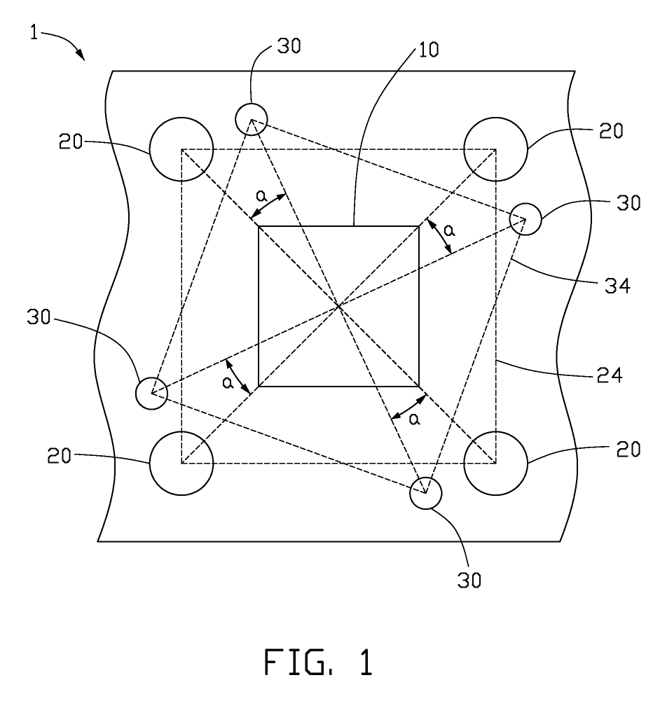

Referring to FIG. 1, a motherboard 1 includes a substantially square-shaped mounting area 10, configured for supporting a central processing unit (CPU). Four first mounting holes 20 are defined in the motherboard 1 around the mounting area 10. Four second mounting holes 30 are defined in the motherboard 1 around the mounting area 10.

In one embodiment, the first mounting holes 20 are located along extension lines of the diagonals of the mounting area 10. The second mounting holes 30 are located adjacent to the corresponding first mounting holes 20. Each of the first mounting holes 20 is located at a corner of a substantially square-shaped area 24, which is concentric with and greater in area than the mounting area 10. Each of the second mounting holes 30 is located at a corner of a substantially square-shaped area 34 concentric with and similar in size to the square-shaped area 24 but rotated around the center point of the square-shaped area 24 to some degree less than or equal to 90 degrees but more than 0 degrees. In other words, the central angle formed by two adjacent holes 20 and 30 with the center is less than 90 degrees.

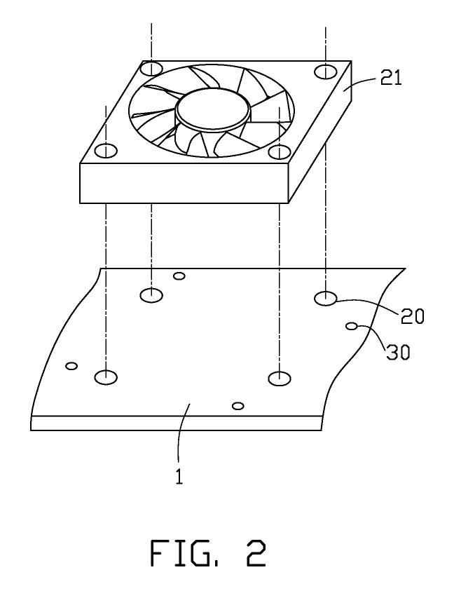

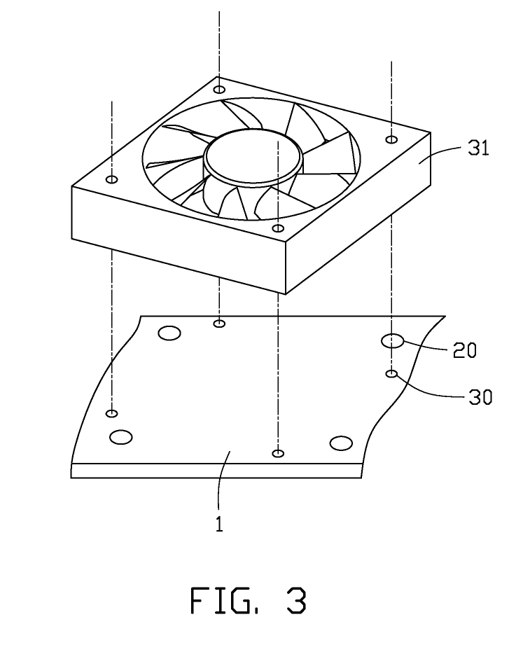

Referring to FIGS. 2 and 3, in use, the four first mounting holes 20 are configured to mount a first fan 21 as shown in FIG. 2, such as an Intel socket 1156 CPU fan. The four second mounting holes 30 are configured to mount a second fan 31 as shown in FIG. 3, such as an Intel socket 775 CPU fan. As a result, the first fan and the second fan can be selectively mounted on the mounting area 10 as desired.

In one embodiment, the mounting area 10 is configured to mount a CPU beneath the selected fan as an example. In other embodiments, the mounting area 10 can be used to mount an electronic component other than a CPU.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skills in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A motherboard comprising:
a mounting area configured to support an electronic component;
a plurality of first mounting holes defined in the motherboard around the mounting area to bound a first area, configured to mount a first type of fan; and
a plurality of second mounting holes defined in the motherboard around the mounting area to bound a second area, configured to mount a second type of fan;
wherein the first and second areas are concentric with the mounting area, and each of the plurality of second mounting holes is located adjacent to a corresponding one of the plurality of first mounting holes.

2. The motherboard of claim 1, wherein the mounting area is substantially square-shaped.

3. The motherboard of claim 2, wherein the plurality of first mounting holes comprises four first mounting holes, the four first mounting holes are arranged along extension lines of two diagonals of the mounting area, and the first area is substantially square-shaped; wherein the plurality of second mounting holes comprises four second mounting holes, the second area is substantially square-shaped.

4. The motherboard of claim 1, wherein an angle between the first and second areas around the center point of the mounting area is smaller than 90 degrees.

5. A motherboard comprising:
a first substantially square-shaped area;
a second substantially square-shaped area at an angle relative to the first area, and sharing a same center with the first area;
four first mounting holes configured to mounting a first fan; and
four second mounting holes configured to mount a second fan;
wherein each of the first holes is located at a corner of the first area, each of the second holes is located at a corner of the second area.

6. The motherboard of claim 5, further comprising a mounting area configured to hold an electronic component, the mounting area is defined inside the first and the second areas, and sharing the same center with the first and the second areas.

7. The motherboard of claim 5, wherein the mounting area is substantially square-shaped.

8. The motherboard of claim 5, wherein the four first mounting holes are arranged on extension lines of two diagonals of the mounting area; wherein each of the second holes is arranged adjacent to a corresponding first mounting hole.

9. The motherboard of claim 5, wherein a central angle formed by two adjacent first hole and second hole with the center is less than 90 degrees.

10. A computer assembly comprising:
a motherboard comprising:
a mounting area defined on the motherboard, mounted with an electronic component, and having a center point;
a plurality of first holes defined in the motherboard configured to mount a first fan, each of the first holes being spaced a first distance apart from the center point of the mounting area; and
a plurality of second holes defined in the motherboard configured to mount a second fan, each of the second holes being spaced a second distance apart from the center point of the mounting area;
wherein the first and the second holes are located surrounding the mounting area, an angle is formed between a first hole and a corresponding second hole relative to the center point of the mounting area.

11. The computer assembly of claim 10, wherein the plurality of first holes comprises four first holes, the plurality of second holes comprises four second holes.

12. The computer assembly of claim 10, wherein the mounting area is substantially square-shaped.

13. The computer assembly of claim 10, wherein the electronic component is a central processing unit.
